(19) United States
(12) Patent Application Publication
(10) Pub. No.: US 2024/0195332 A1
(43) Pub. Date: Jun. 13, 2024

(54) ELECTROSTATIC CHUCK

(71) Applicant: KYOCERA Corporation, Kyoto-shi, Kyoto (JP)

(72) Inventor: Kenichi AKABANE, Kirishima-shi (JP)

(73) Assignee: KYOCERA Corporation, Kyoto-shi, Kyoto (JP)

(21) Appl. No.: 18/552,282

(22) PCT Filed: Mar. 1, 2022
(86) PCT No.: PCT/JP2022/008593

§ 371 Date: Sep. 25, 2023

(30) Foreign Application Priority Data
Mar. 25, 2021 (JP) 2021-052408

(51) Int. Cl. H02N 13/00; B23Q 3/15

(52) U.S. Cl. CPC H02N 13/00; B23Q 3/15

(57) ABSTRACT

An electrostatic chuck includes a ceramic substrate, a base plate, and an embedded member. The ceramic substrate includes a first surface on which a to-be-treated object is placed, a second surface opposite to the first surface, and a first channel penetrating through the first surface and the second surface. The base plate is bonded to the second surface of the ceramic substrate and includes a through hole at least at a position corresponding to the first channel. The embedded member is located in the through hole and includes a porous body facing the first channel and a second channel communicating with the first channel via the porous body. The first channel and the second channel are located apart from each other in a plane perspective view.

### CROSS-REFERENCE TO RELATED APPLICATIONS

This application is national stage application of International Application No. PCT/JP2022/008593, filed on Mar. 1, 2022, which designates the United States, incorporated herein by reference, and which claims the benefit of priority from Japanese Patent Application No. 2021-052408, filed on Mar. 25, 2021, the entire contents of which are incorporated herein by reference.

### TECHNICAL FIELD

An embodiment of the present disclosure relates to an electrostatic chuck.

### BACKGROUND OF INVENTION

In a manufacturing process of a semiconductor part, an electrostatic chuck is used to hold a to-be-treated object such as a semiconductor wafer to be subjected to a plasma treatment. The electrostatic chuck is configured by, for example, bonding to a metal base plate a ceramic substrate including an electrode embedded therein. In the electrostatic chuck, a channel for supplying a heat transfer gas for temperature control to the to-be-treated object placed on the electrostatic chuck is formed.

From the viewpoint of suppressing entry of plasma into the channel, an electrostatic chuck in which a porous body is disposed in the channel is proposed (for example, see Patent Document 1).

### CITATION LIST

### Patent Literature

### Patent Document 1: JP 2019-165223 A

### SUMMARY

In an aspect of an embodiment, an electrostatic chuck includes a ceramic substrate, a base plate, and an embedded member. The ceramic substrate includes a first surface on which a to-be-treated object is placed, a second surface opposite to the first surface, and a first channel penetrating through the first surface and the second surface. The base plate is bonded to the second surface of the ceramic substrate and includes a through hole at least at a position corresponding to the first channel. The embedded member is located in the through hole and includes a porous body facing the first channel and a second channel communicating with the first channel via the porous body. The first channel and the second channel are located apart from each other in a plane perspective view.

### BRIEF DESCRIPTION OF THE DRAWINGS

FIG. 1 is a perspective view illustrating a configuration of an electrostatic chuck according to an embodiment.

FIG. 2 is a schematic view illustrating a cross section of the electrostatic chuck in FIG. 1.

FIG. 3 is a plan view illustrating an example of a configuration of a ceramic substrate included in the electrostatic chuck in FIG. 1 when viewed from above.

FIG. 4 is a schematic view illustrating a cross section of the electrostatic chuck according to a first variation of the embodiment.

FIG. 5 is a plan view illustrating an example of a configuration of a ceramic substrate included in the electrostatic chuck in FIG. 4 when viewed from above.

FIG. 6 is a schematic view illustrating a cross section of the electrostatic chuck according to a second variation of the embodiment.

FIG. 7 is a plan view illustrating an example of a configuration of a ceramic substrate included in the electrostatic chuck in FIG. 6 when viewed from above.

FIG. 8 is a schematic view illustrating a cross section of the electrostatic chuck according to a third variation of the embodiment.

FIG. 9 is a cross-sectional view of an embedded member included in the electrostatic chuck in FIG. 8.

FIG. 10 is a schematic view illustrating a cross section of the electrostatic chuck according to a fourth variation of the embodiment.

FIG. 11 is a cross-sectional view of an embedded member included in the electrostatic chuck in FIG. 10.

FIG. 12 is a schematic view illustrating a cross section of the electrostatic chuck according to a fifth variation of the embodiment.

FIG. 13 is a cross-sectional view of an embedded member included in the electrostatic chuck in FIG. 12.

### DESCRIPTION OF EMBODIMENTS

Hereinafter, embodiments of an electrostatic chuck disclosed in the present disclosure will be described with reference to the accompanying drawings. The present disclosure is not limited by the following embodiment. Note that the drawings are schematic and that the dimensional relationships between elements, the proportions thereof, and the like may differ from the actual ones. There may be differences between the drawings in the dimensional relationships, proportions, and the like.

In the embodiments described below, expressions such as “constant”, “orthogonal”, “perpendicular”, and “parallel” may be used, but these expressions do not need to be exactly “constant”, “orthogonal”, “perpendicular”, and “parallel”. In other words, it is assumed that the above expressions allow deviations in manufacturing accuracy, installation accuracy, or the like.

### Embodiments

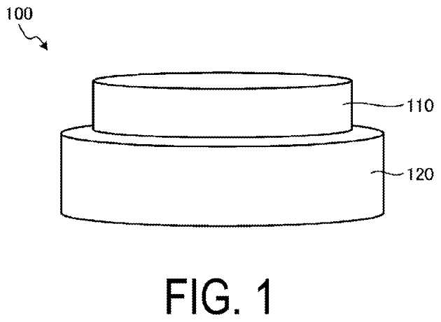

FIG. 1 is a perspective view illustrating a configuration of an electrostatic chuck 100 according to an embodiment. The electrostatic chuck 100 illustrated in FIG. 1 has a structure in which a ceramic substrate 110 and a base plate 120 are bonded to each other.

The ceramic substrate 110 adsorbs a to-be-treated object such as a semiconductor wafer by using an electrostatic force.

The base plate 120 is a support member that supports the ceramic substrate 110. The base plate 120 is attached to, for example, a semiconductor manufacturing device, and causes the electrostatic chuck 100 to function as a semiconductor holding device that holds the to-be-treated object such as a semiconductor wafer.

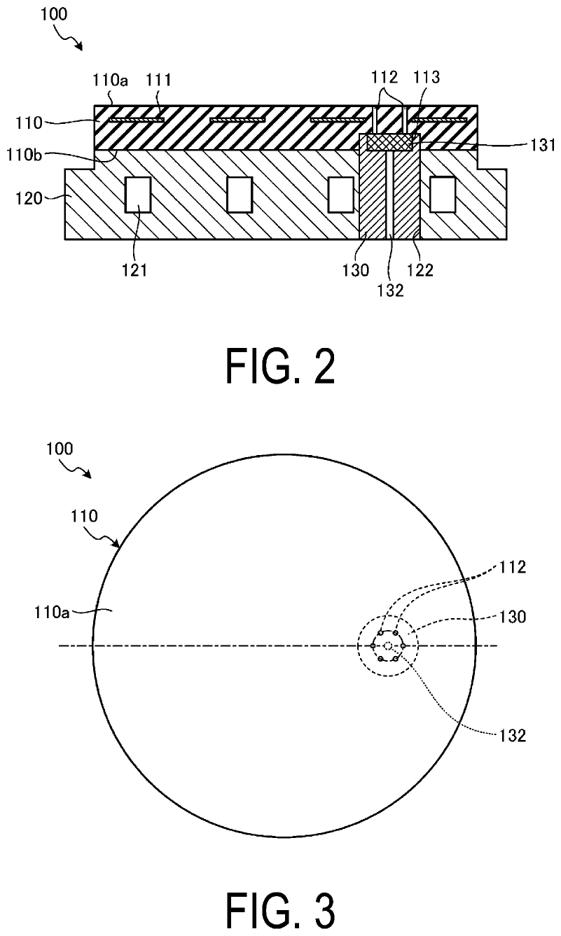

FIG. 2 is a schematic view illustrating a cross section of the electrostatic chuck 100 in FIG. 1. As described above, the electrostatic chuck 100 is configured by bonding the ceramic substrate 110 and the base plate 120.

The ceramic substrate 110 is a member obtained by molding a raw material containing ceramic into a substantially disk shape. The ceramic substrate 110 contains, for example, aluminum oxide (Al₂O₃), aluminum nitride (AlN), yttria (Y₂O₃), cordierite, silicon carbide (SiC), silicon nitride (Si₃N₄), or the like as a main component.

The ceramic substrate 110 includes a first surface 110a on which the to-be-treated object such as a semiconductor wafer is placed and a second surface 110b opposite to the first surface 110a. The to-be-treated object placed on the first surface 110a of the ceramic substrate 110 is treated by generating plasma above the first surface 110a. The plasma can be generated by applying high-frequency power to a facing electrode to excite a gas.

An electrode 111 is provided inside the ceramic substrate 110. The electrode 111 is, for example, an electrode for electrostatic adsorption and is an electrically conductive member containing a metal such as platinum, tungsten, or molybdenum. When a voltage is applied, the electrode 111 generates an electrostatic force to adsorb the to-be-treated object to the first surface 110a of the ceramic substrate 110.

The base plate 120 is bonded to the second surface 110b of the ceramic substrate 110. The base plate 120 may be bonded to the second surface 110b via, for example, a bonding material. As the bonding material, an adhesive such as a silicone resin or the like can be used.

The base plate 120 is a circular member made of metal. As a metal material forming the base plate 120, for example, aluminum or stainless steel can be used.

The base plate 120 may include a space 121 therein. The space 121 may be used as a refrigerant passage through which a cooling medium such as cooling water or cooling gas passes. The base plate 120 may also function as a high-frequency electrode to which high-frequency power for plasma generation is applied.

As illustrated in FIG. 2, a plurality of first channels 112 penetrating through the first surface 110a and the second surface 110b are formed in the ceramic substrate 110.

A through hole 122 is formed in the base plate 120 at least at a position corresponding to the plurality of first channels 112, and an embedded member 130 is disposed in the through hole 122.

The embedded member 130 is, for example, a columnar member made of an insulation material such as aluminum oxide (Al₂O₃). When a recessed portion 113 is provided in the second surface 110b of the ceramic substrate 110, the embedded member 130 may be fitted into the recessed portion 113 and protrude toward the ceramic substrate 110 side from the upper surface (that is, the surface bonded to the second surface 110b) of the base plate 120. Accordingly, since a length of each of the first channels 112 is shortened at the position corresponding to the recessed portion 113 of the ceramic substrate 110, the generation of plasma in the first channels 112 can be suppressed.

The embedded member 130 includes a porous body 131 at an end portion on the side of the first channels 112. Since the porous body 131 is located at the end portion on the side of the first channels 112, when the plasma is generated above the first surface 110a of the ceramic substrate 110, a problem that plasma passes through the first channel 112 and reaches the base plate 120 side can be reduced.

The porous body 131 is, for example, an alumina porous body or another ceramic porous body. The porous body 131 may include voids to such an extent that a gas can flow, and porosity of the porous body 131 is, for example, 40% or more and 60% or less.

A second channel 132 communicating with the plurality of the first channels 112 via the porous body 131 is formed in the embedded member 130. The second channel 132 and the first channels 112 form a gas-flow passage continuing from a lower surface of the base plate 120 to an upper surface (first surface 110a) of the ceramic substrate 110 via the porous body 131. For example, a heat transfer gas such as helium may be allowed to flow through the second channel 132 and the first channels 112. By allowing the heat transfer gas to flow through the second channel 132 and the first channels 112, the heat transfer gas is supplied to the back surface of the to-be-treated object placed on the first surface 110a of the ceramic substrate 110, and the heat transfer coefficient between the to-be-treated object and the ceramic substrate 110 is improved.

The first channels 112 and the second channel 132 are located at respective positions where each of the first channels 112 and the second channel 132 do not overlap each other in a plan view (that is, when viewed from a direction perpendicular to the first surface 110a).

FIG. 3 is a plan view illustrating an example of a configuration of the ceramic substrate 110 included in the electrostatic chuck 100 in FIG. 1 when viewed from above. In FIG. 3, the first surface 110a of the ceramic substrate 110 is illustrated in a disk shape. The plurality of first channels 112 is located at positions surrounding the second channel 132 in a plan view (that is, when viewed from a direction perpendicular to the first surface 110a). In the example in FIG. 3, six first channels 112 are located at equal intervals on a concentric circle centered on a central axis of one second channel 132.

For example, a case is assumed in which the first channels 112 and the second channel 132 are linearly located from the upper surface (first surface 110a) of the ceramic substrate 110 to the lower surface of the base plate 120. In this case, when the plasma is generated above the first surface 110a, charged particles in the plasma may enter the first channels 112 while maintaining high energy, reach the porous body 131 or the second channel 132, and abnormal discharge may occur in the porous body 131 or the second channel 132.

On the other hand, in the present embodiment, as illustrated in FIGS. 2 and 3, the first channels 112 and the second channel 132 are disposed at respective positions where each of the first channels 112 and the second channel 132 do not overlap each other in a plan view to form a gas-flow passage having a structure that bends in a direction parallel to the first surface 110a, that is, a labyrinthine structure. Accordingly, when the plasma is generated above the first surface 110a, even if charged particles in the plasma enter the first channels 112, the charged particles come into contact with the wall surface of the voids in the porous body 131 and the wall surface of the second channel and are deactivated. As a result, in the present embodiment, according to the electrostatic chuck 100, an occurrence of the abnormal discharge in the first channels and the second channel can be suppressed.

Since the plurality of first channels 112 is located at the positions surrounding the second channel 132 in a plan view, when the heat transfer gas is supplied to the back surface of the to-be-treated object placed on the first surface 110a, the heat transfer gas is dispersed to each of the first channels 112, and thus the gas pressure in each of the first channels 112 is reduced. As a result, in the present embodiment, according to the electrostatic chuck 100, the occurrence of the abnormal discharge due to an increase in the gas pressure of the heat transfer gas in each of the first channels 112 can be suppressed.

### Variation

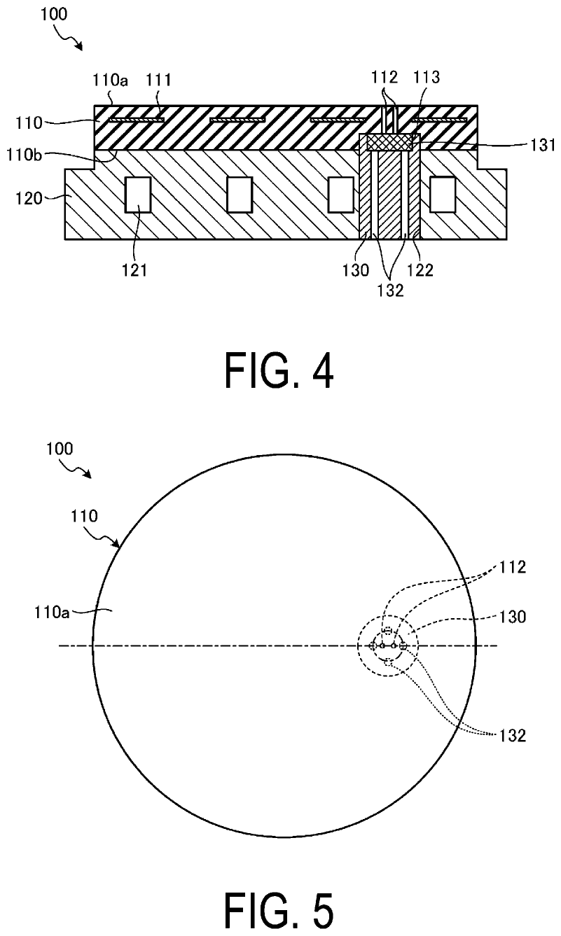

The number and disposition of the first channel 112 and the second channel 132 are not limited to the examples in FIGS. 2 and 3. FIG. 4 is a schematic view illustrating a cross section of the electrostatic chuck 100 according to a first variation of the embodiment.

As illustrated in FIG. 4, a plurality of second channels 132 communicating with the plurality of the first channels 112 via the porous body 131 is formed in the embedded member 130 according to the first variation. As with the first channels 112 and the second channel 132 illustrated in FIG. 2, the first channels 112 and the second channels 132 are located at respective positions where each of the first channels 112 and each of the second channels do not overlap each other in a plan view (that is, when viewed from a direction perpendicular to the first surface 110a).

FIG. 5 is a plan view illustrating an example of a configuration of the ceramic substrate 110 included in the electrostatic chuck 100 in FIG. 4 when viewed from above. In FIG. 5, the first surface 110a of the ceramic substrate 110 is illustrated in a disk shape. The plurality of second channels 132 is located at positions surrounding the first channels 112 in a plan view (that is, when viewed from a direction perpendicular to the first surface 110a). In the example in FIG. 5, four second channels 132 are located at equal intervals on a concentric circle centered on a center position of a line segment connecting two first channels 112. Since the plurality of second channels 132 is located at the positions surrounding the first channels 112 in a plan view, when the heat transfer gas is supplied to the back surface of the to-be-treated object placed on the first surface 110a, the heat transfer gas is dispersed to each of the second channels 132, and thus the gas pressure in each of the second channels 132 is reduced. As a result, in the present first variation, according to the electrostatic chuck 100, the occurrence of the abnormal discharge in each of the second channels 132 due to an increase in the gas pressure of the heat transfer gas can be suppressed.

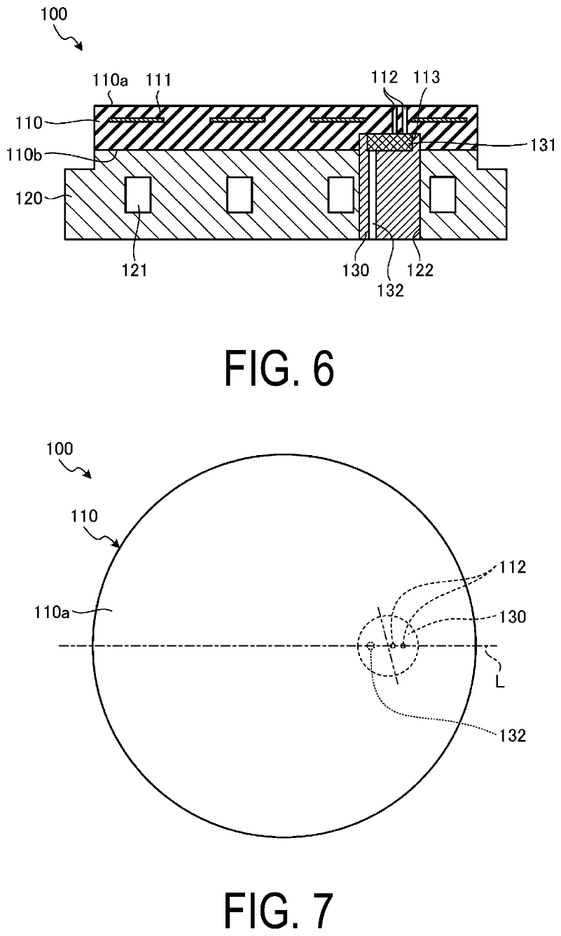

FIG. 6 is a schematic view illustrating a cross section of the electrostatic chuck 100 according to a second variation of the embodiment. FIG. 7 is a plan view illustrating an example of a configuration of the ceramic substrate 110 included in the electrostatic chuck 100 in FIG. 6 when viewed from above. In FIG. 7, the first surface 110a of the ceramic substrate 110 is illustrated in a disk shape.

As illustrated in FIGS. 6 and 7, the plurality of first channels 112 and the second channel 132 according to the second variation are provided in the first region and the second region, respectively. The first region in which the first channels 112 are provided and the second region in which the second channel 132 is provided are located at positions where they do not overlap each other in a plane perspective view (that is, when viewed from a direction perpendicular to the first surface 110a) and positions separated from each other. For example, the first region in which the first channels 112 are provided and the second region in which the second channel 132 is provided are located at positions where they do not overlap each other in a plane perspective view and positions separated from each other along a straight line L passing through the center of the ceramic substrate 110. When the first channels 112 and the second channel 132 are located at positions where they do not overlap each other and are separated from each other in a plan view, the expansion direction due to thermal expansion of the ceramic substrate 110 and the base plate 120 can be set to the same direction of each of the first channels 112 and the second channel 132. As a result, in the second variation, according to the electrostatic chuck 100, even when thermal expansion of the ceramic substrate 110 and the base plate 120 occurs, a problem caused by a shift in the positional relationship between each of the first channels 112 and the second channel 132 can be reduced. In the examples illustrated in FIGS. 6 and 7, the examples in which each of the first channels 112 and the second channel 132 are located at positions separated from each other along the straight line L, but the direction in which each of the first channels 112 and the second channel 132 are separated from each other may be different from the direction along the straight line L.

From another viewpoint, as illustrated in FIGS. 6 and 7, each of the first channels 112 may be located on one side and the second channel 132 may be located on the other side with respect to a virtual line including the center of the embedded member 130 in a plane perspective view. The alternate long and two short dashed line illustrated in FIG. 7 is a virtual line including the center of the embedded member in a plane perspective view. Accordingly, the charged particles are less likely to reach the second channel 132, and the occurrence of the abnormal discharge in the second channel 132 is reduced.

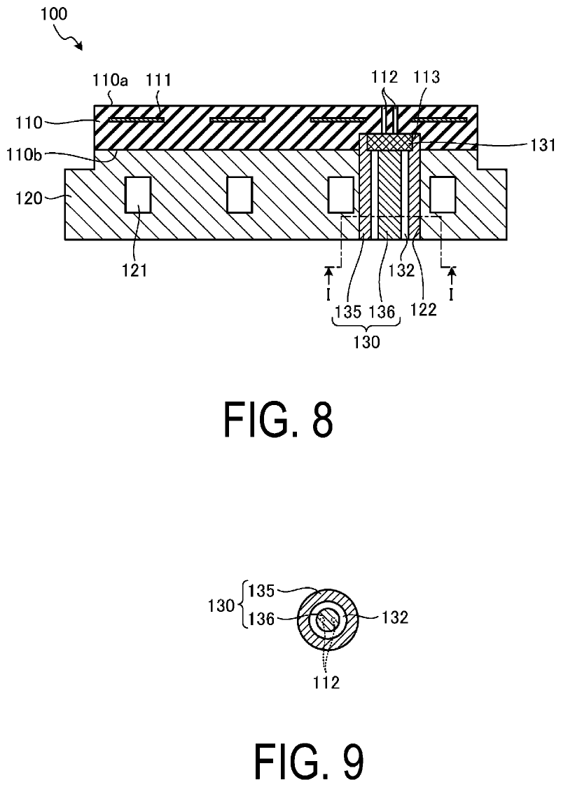

In the above-described embodiment, the case where the second channel 132 is formed in the columnar embedded member 130 is described as an example. However, the second channel 132 may be formed by a plurality of members obtained by dividing the embedded member 130. FIGS. 8 to 13 below illustrate other examples of the embedded member 130.

FIG. 8 is a schematic view illustrating a cross section of the electrostatic chuck 100 according to a third variation of the embodiment. FIG. 9 is a cross-sectional view of an embedded member 130 included in the electrostatic chuck 100 in FIG. 8. FIG. 9 illustrates a cross section taken along the arrow direction of the line I-I in FIG. 8.

The embedded member 130 illustrated in FIGS. 8 and 9 is divided into a cylindrical portion 135 and a columnar portion 136 located in the cylindrical portion 135. The cylindrical portion 135 is located along an inner wall of the through hole 122 in the base plate 120 and includes a space therein. The columnar portion 136 is located in the space inside the cylindrical portion 135, spaced apart from an inner peripheral surface of the cylindrical portion 135. The columnar portion 136 may be fixed to the porous body 131 by an adhesive or the like. The second channel 132 is formed by the inner peripheral surface of the cylindrical portion 135 and an outer peripheral surface of the columnar portion 136. In other words, the space between the inner peripheral surface of the cylindrical portion 135 and the outer peripheral surface of the columnar portion 136 is the second channel 132. More specifically, the second channel 132 is formed in an annular shape surrounding the columnar portion 136 in a plane perspective view (that is, when viewed from a direction perpendicular to the first surface 110a).

As described above, when the second channel 132 is formed by the inner peripheral surface of the cylindrical portion 135 and the outer peripheral surface of the columnar portion 136, for example, even when stress is applied to the cylindrical portion 135 due to thermal expansion of the base plate 120, the stress is absorbed in the second channel 132. Thus, in the third variation, according to the electrostatic chuck 100, for example, the performance deterioration due to heat cycle can be reduced.

When the second channel 132 annularly surrounds the columnar portion 136, for example, even in a case where the cylindrical portion 135 is deformed due to long-term heat cycle and distortion in the radial direction occurs, the columnar portion 136 is less likely to receive an external force that causes damage. Thus, in the third variation, according to the electrostatic chuck 100, the performance deterioration due to heat cycle can be reduced for a long time.

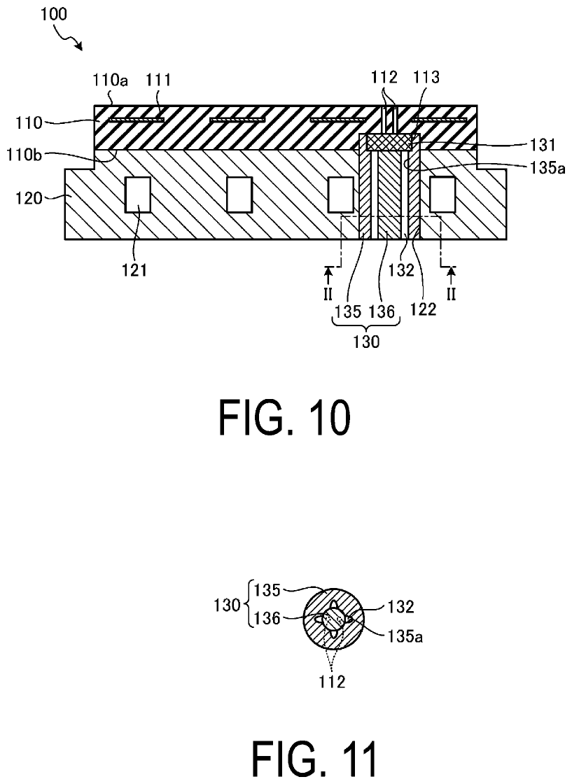

FIG. 10 is a schematic view illustrating a cross section of the electrostatic chuck 100 according to a fourth variation of the embodiment. FIG. 11 is a cross-sectional view of the embedded member 130 included in the electrostatic chuck 100 in FIG. 10. FIG. 11 illustrates a cross section taken along the arrow direction of the line II-II in FIG. 10.

The embedded member 130 illustrated in FIGS. 10 and 11 is divided into the cylindrical portion 135 and the columnar portion 136. The cylindrical portion 135 is located along the inner wall of the through hole 122 in the base plate 120, includes a space therein, and includes a groove 135a extending in the axial direction of the through hole 122 in the inner peripheral surface of the cylindrical portion 135. In other words, the cylindrical portion 135 includes a first equal-diameter portion (a portion excluding the groove 135a) having the same diameter as that of the outer peripheral surface of the columnar portion 136 and a first different-diameter portion (a portion including the groove 135a) having a different diameter from that of the outer peripheral surface of the columnar portion 136. The columnar portion 136 is located in the space inside the cylindrical portion 135 along the inner peripheral surface of the cylindrical portion 135. The columnar portion 136 may be fixed to the porous body 131 by an adhesive or the like. The second channel 132 is formed by the inner wall surface of the groove 135a and the outer peripheral surface of the columnar portion 136. In other words, a space between the first different-diameter portion (a portion including the groove 135a) of the cylindrical portion 135 and the outer peripheral surface of the columnar portion 136 is the second channel 132.

As described above, when the second channel 132 is formed by the inner wall surface of the groove 135a and the outer peripheral surface of the columnar portion 136, for example, the channel area of the second channel 132 can be enlarged outward in the radial direction of the porous body 131 in accordance with the depth of the groove 135a. Thus, in the fourth variation, according to the electrostatic chuck 100, for example, when the heat transfer gas is supplied to the back surface of the to-be-treated object placed on the first surface 110a, the heat transfer gas easily flows in the radial direction of the porous body 131, thus suppressing the abnormal discharge in the second channel 132.

The columnar portion 136 may be located in the space inside the cylindrical portion 135, spaced apart from the inner peripheral surface of the cylindrical portion 135.

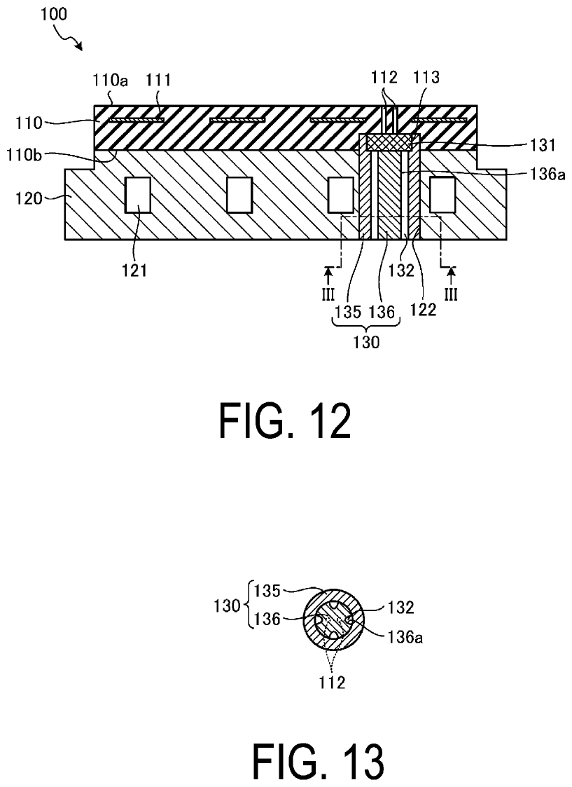

FIG. 12 is a schematic view illustrating a cross section of the electrostatic chuck 100 according to a fifth variation of the embodiment. FIG. 13 is a cross-sectional view of the embedded member 130 included in the electrostatic chuck 100 in FIG. 12. FIG. 13 illustrates a cross section taken along the arrow direction of the line III-III in FIG. 12.

The embedded member 130 illustrated in FIGS. 12 and 13 is divided into the cylindrical portion 135 and the columnar portion 136. The cylindrical portion 135 is located along the inner wall of the through hole 122 and includes a space therein. The columnar portion 136 is located in the space inside the cylindrical portion 135 along the inner peripheral surface of the cylindrical portion 135, and includes a groove 136a extending in the axial direction of the through hole 122 in the outer peripheral surface of the columnar portion 136. In other words, the columnar portion 136 includes a second equal-diameter portion (a portion excluding the groove 136a) having the same diameter as that of the inner peripheral surface of the cylindrical portion 135 and a second different-diameter portion (a portion including the groove 136a) having a different diameter from that of the inner peripheral surface of the cylindrical portion 135. The second channel 132 is formed by the inner peripheral surface of the cylindrical portion 135 and an inner wall surface of the groove 136a. In other words, a space between the inner peripheral surface of the cylindrical portion 135 and the second different-diameter portion (a portion including the groove 136a) is the second channel 132.

As described above, when the second channel 132 is formed by the inner peripheral surface of the cylindrical portion 135 and the inner wall surface of the groove 136a, the strength of the cylindrical portion 135 which is susceptible to receive stresses due to thermal expansion of the base plate 120 can be maintained. Thus, in the fifth variation, according to the electrostatic chuck 100, for example, the performance deterioration due to heat cycle can be reduced.

As described above, the electrostatic chuck (for example, the electrostatic chuck 100) according to the embodiment includes the ceramic substrate (for example, the ceramic substrate 110), the base plate (for example, the base plate 120), and the embedded member (for example, the embedded member 130). The ceramic substrate includes the first surface (for example, the first surface 110a) on which the to-be-treated object is placed, the second surface (for example, the second surface 110b) located opposite to the first surface, and the first channel (for example, the first channel 112) penetrating through the first surface and the second surface. The base plate is bonded to the second surface of the ceramic substrate and includes a through hole (for example, the through hole 122) at least at the position corresponding to the first channel. The embedded member is located in the through hole and includes the porous body (for example, the porous body 131) facing the first channel and the second channel (for example, the second channel 132) communicating with the first channel via the porous body. The first channel and the second channel are located apart from each other in a plane perspective view. Accordingly, the occurrence of the abnormal discharge in the channels (that is the first channel and the second channel) can be suppressed.

In the embodiment, the ceramic substrate may include a plurality of first channels. The plurality of first channels may be located to surround the second channel in a plane perspective view. Accordingly, the occurrence of the abnormal discharge due to an increase in the gas pressure of the heat transfer gas in each of the first channels can be suppressed.

In the embodiment, the embedded member may include a plurality of second channels. The plurality of second channels may be located to surround the first channel in a plane perspective view. Accordingly, the occurrence of the abnormal discharge due to an increase in the gas pressure of the heat transfer gas in each of the second channels can be suppressed.

In the embodiment, the embedded member may include a cylinder portion (for example, the cylindrical portion 135) and a column portion (for example, the columnar portion 136) located inside the cylinder portion, and the second channel may be between the inner peripheral surface of the cylinder portion and the outer peripheral surface of the column portion. Accordingly, the performance decrease due to heat cycle can be reduced.

In the embodiment, the second channel may be formed in an annular shape surrounding the column portion in a plane perspective view. Accordingly, the performance decrease due to heat cycle can be reduced for a long time.

In the embodiment, the cylinder portion may include the first equal-diameter portion having the same diameter as that of the outer peripheral surface and the first different-diameter portion having a different diameter from that of the outer peripheral surface, and the second channel may be between the first different-diameter portion and the outer peripheral surface. Accordingly, the abnormal discharge in the second channel can be suppressed.

In the embodiment, the column portion may include the second equal-diameter portion having the same diameter as that of the inner peripheral surface and the second different-diameter portion having a different diameter from that of inner peripheral surface, and the second channel may be between the inner peripheral surface and the second different-diameter portion. Accordingly, the performance decrease due to heat cycle can be reduced.

As illustrated in FIGS. 6 and 7, in the plurality of first channels and the second channel according to the embodiment, the first channel may be located on one side and the second channel may be located on the other side with respect to the virtual line including the center of the embedded member in a plane perspective view. The alternate long and two short dashed line illustrated in FIG. 7 is a virtual line including the center of the embedded member in a plane perspective view. Accordingly, the charged particles are less likely to reach the second channel, and the occurrence of the abnormal discharge in the second channel is reduced.

Further effects and variations can be readily derived by those skilled in the art. Thus, a wide variety of aspects of the present invention are not limited to the specific details and representative embodiments represented and described above. Accordingly, various changes are possible without departing from the spirit or scope of the general inventive concepts defined by the appended claims and their equivalents.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

1. An electrostatic chuck comprising:
a ceramic substrate comprising:
a first surface on which a to-be-treated object is placed;
a second surface opposite to the first surface; and
a first channel penetrating through the first surface and the second surface;
a base plate bonded to the second surface of the ceramic substrate and comprising a through hole at least at a position corresponding to the first channel; and
an embedded member located in the through hole and comprising a porous body facing the first channel and a second channel communicating with the first channel via the porous body, the first channel and the second channel being located apart from each other in a plane perspective view.

2. The electrostatic chuck according to claim 1, wherein the ceramic substrate comprises a plurality of the first channels.

3. The electrostatic chuck according to claim 2, wherein the plurality of first channels are located to surround the second channel in a plane perspective view.

4. The electrostatic chuck according to claim 1, wherein the embedded member comprises a plurality of the second channels.

5. The electrostatic chuck according to claim 4, wherein the plurality of second channels are located to surround the first channel in a plane perspective view.

6. The electrostatic chuck according to claim 1, wherein
the embedded member comprises a cylinder portion and a column portion located in the cylinder portion, and
the second channel is between an inner peripheral surface of the cylindrical portion and an outer peripheral surface of the column portion.

7. The electrostatic chuck according to claim 6, wherein the second channel is formed in an annular shape surrounding the column portion in a plane perspective view.

8. The electrostatic chuck according to claim 6, wherein
the cylinder portion comprises a first equal-diameter portion having a same diameter as that of the outer peripheral surface and a first different-diameter portion having a different diameter from that of the outer peripheral surface, and
the second channel is between the first different-diameter portion and the outer peripheral surface.

9. The electrostatic chuck according to claim 6, wherein
the column portion comprises a second equal-diameter portion having a same diameter as that of the inner peripheral surface and a second different-diameter portion having a different diameter from that of the inner peripheral surface, and
the second channel is between the inner peripheral surface and the second different-diameter portion.

10. The electrostatic chuck according to claim 1, wherein
the first channel is located on one side and the second channel is located on the other side with respect to a virtual line comprising a center of the embedded member in a plane perspective view.
